(19) United States
(12) Patent Application Publication
(10) Pub. No.: US 2026/0063710 A1
(43) Pub. Date: Mar. 5, 2026

(54) APPARATUS AND METHODS FOR JITTER TESTING OF CLOCK SIGNALS

(71) Applicant: Skyworks Solutions, Inc., Irvine, CA (US)

(72) Inventors: Sanjeev Tannirkulam Chandrasekaran, Austin, TX (US); Raghunandan Kolar Ranganathan, Round Rock, TX (US); Kannanthodath V. Jayakumar, Austin, TX (US); Srisai Rao Seethamraju, Nashua, NH (US)

(21) Appl. No.: 19/309,066

(22) Filed: Aug. 25, 2025

Related U.S. Application Data
(60) Provisional application No. 63/688,412, filed on Aug. 29, 2024.

(51) Int. Cl. G01R 31/317; H03L 7/08

(52) U.S. Cl. CPC G01R 31/31709; G01R 31/31727; H03L 7/08

(57) ABSTRACT

Apparatus and methods for jitter testing of clock signals are disclosed. In certain embodiments, a jitter measuring circuit is used to obtain jitter measurements of a PLL's clock signal in an analog domain. For example, the analog jitter measurements can be generated by discharging a capacitor to a voltage that is proportional to a phase difference between a test clock signal from the PLL and a reference clock signal that can be assumed to be ideal. Additionally, the analog jitter measurements are digitized and processed (for instance, using digital signal processing) to generate an estimate of jitter.

### CROSS-REFERENCE TO RELATED APPLICATIONS

This application claims the benefit of priority under 35 U.S.C. § 119 of U.S. Provisional Patent Application No. 63/688412, filed Aug. 29, 2024 and titled “APPARATUS AND METHODS FOR JITTER TESTING OF CLOCK SIGNALS,” which is herein incorporated by reference in its entirety.

### BACKGROUND

### Field

Embodiments of the invention relate to electronic systems, and more particularly to, jitter self-test of clock signals from phase-locked loops.

### Description of the Related Technology

A wide variety of electronic systems operate based on timing of clock signals generated by phase-locked loops (PLLs). For instance, examples of such electronic systems include, but are not limited to, high-speed telecommunications systems, network synchronizers, clock generators, data converters, jitter attenuators, oscillators, frequency multipliers, and/or wireline or optical data communication links.

In such electronic systems, the jitter of clock signals generated by the PLLs can lead to a performance degradation. For example, such jitter can correspond to an unwanted deviation from an ideal periodicity of the clock signal. The amount of tolerable jitter varies with a target application. Since jitter can vary from part to part, it is desirable to perform a screening to identify parts having jitter exceeding a target jitter specification.

### SUMMARY

In certain embodiments, the present disclosure relates to a jitter measurement system that includes a jitter measuring circuit configured to obtain a plurality of analog jitter measurements of a test clock signal of a phase-locked loop, an analog-to-digital converter configured to convert the plurality of analog jitter measurements to a plurality of digital jitter measurements, and a digital signal processing circuit configured to process the plurality of digital jitter measurements to estimate a jitter of the test clock signal.

In some embodiments, the jitter measuring circuit includes a capacitor electrically connected between an output node and a first reference voltage, a reference clock voltage-controlled current source controlled by a reference clock signal, and a test clock switch controlled by the test clock signal, the test clock switch and the voltage-controlled current source electrically connected in series between the output node and the first reference voltage. According to a number of embodiments, an output voltage at the output node generates a jitter measurement voltage proportional to a phase difference between the test clock signal and the reference clock signal. In accordance with several embodiments, the jitter measuring circuit further includes a ramp control circuit configured to control a slew of the reference clock signal based on a slew control signal. According to various embodiments, the ramp control signal is operable in a low gain mode associated with locking the phase-locked loop and a high gain mode associated with obtaining the plurality of analog jitter measurements of the test clock signal. In accordance with a number of embodiments, the jitter measuring circuit further includes a reset switch electrically connected between a second reference voltage and the output node. According to several embodiments, the reference clock voltage-controlled current source includes a first n-type metal-oxide-semiconductor transistor, the test clock switch includes a second n-type metal-oxide-semiconductor transistor, and the reset switch includes a p-type metal-oxide-semiconductor transistor.

In various embodiments, the digital signal processing circuit is configured to estimate the jitter of the test clock signal based on one or more statistical calculations on the plurality of digital jitter measurements. According to a number of embodiments, the digital signal processing circuit is configured to estimate the jitter of the test clock signal based on a first derivative of the plurality of digital jitter measurements. In accordance with some embodiments, the digital signal processing circuit is further configured to estimate the jitter of the test clock signal based on a standard deviation or variance of the first derivative of the plurality of digital jitter measurements.

In various embodiments, the digital signal processing circuit is configured to compare the estimate of the jitter of the test clock signal to a reference jitter threshold. According to a number of embodiments, the digital signal processing circuit is further configured to generate the reference jitter threshold from a plurality of digital reference jitter measurements obtained from an input clock signal of a known jitter.

In some embodiments, the jitter measuring circuit and the phase-locked loop are implemented on a common semiconductor chip. According to a number of embodiments, the phase-locked loop includes a time-stamper including the analog-to-digital converter. In accordance with several embodiments, the time-stamper is operable in a first mode in which the analog-to-digital converter outputs digital data for generating digital time stamps, and a second mode in which the analog-to-digital converter outputs the plurality of digital jitter measurements for jitter testing.

In several embodiments, the analog-to-digital converter includes a differential voltage input and the jitter measuring circuit includes a single-ended voltage output, the jitter measurement system further including a single-ended to differential voltage buffer coupled between the single-ended voltage output and the differential voltage input.

In various embodiments, the jitter measuring circuit includes a capacitor electrically connected between a sampling node and a first reference voltage, a buffer, and a sampling switch controlled by the test clock signal and electrically connected between the sampling node and an input to the buffer. According to a number of embodiments, the jitter measuring circuit further includes a resistor electrically connected between the sampling node and a second reference voltage. In accordance with several embodiments, the jitter measuring circuit further includes a current source electrically connected between the sampling node and a second reference voltage. According to some embodiments, the jitter measuring circuit further includes a reset switch electrically connected between the sampling node and the first reference voltage.

In certain embodiments, the present disclosure relates to a method of jitter measurement, the method including obtaining a plurality of analog jitter measurements of a test clock signal of a phase-locked loop using a jitter measuring circuit, converting the plurality of analog jitter measurements to a plurality of digital jitter measurements using an analog-to-digital converter, and processing the plurality of digital jitter measurements to estimate a jitter of the test clock signal using a digital signal processing circuit.

In some embodiments, the jitter measuring circuit includes a capacitor electrically connected between an output node and a first reference voltage, a reference clock voltage-controlled current source controlled by a reference clock signal, and a test clock switch controlled by the test clock signal, the test clock switch and the voltage-controlled current source electrically connected in series between the output node and the first reference voltage. According to a number of embodiments, an output voltage at the output node generates a jitter measurement voltage proportional to a phase difference between the test clock signal and the reference clock signal. In accordance with several embodiments, the jitter measuring circuit further includes a ramp control circuit configured to control a slew of the reference clock signal based on a slew control signal. According to various embodiments, the ramp control signal is operable in a low gain mode associated with locking the phase-locked loop and a high gain mode associated with obtaining the plurality of analog jitter measurements of the test clock signal. In accordance with a number of embodiments, the jitter measuring circuit further includes a reset switch electrically connected between a second reference voltage and the output node. According to several embodiments, the reference clock voltage-controlled current source includes a first n-type metal-oxide-semiconductor transistor, the test clock switch includes a second n-type metal-oxide-semiconductor transistor, and the reset switch includes a p-type metal-oxide-semiconductor transistor.

In various embodiments, the method further includes using the digital signal processing circuit to estimate the jitter of the test clock signal based on one or more statistical calculations on the plurality of digital jitter measurements. According to a number of embodiments, the method further includes using the digital signal processing circuit to estimate the jitter of the test clock signal based on a first derivative of the plurality of digital jitter measurements. In accordance with several embodiments, the method further includes using the digital signal processing circuit to estimate the jitter of the test clock signal based on a standard deviation or variance of the first derivative of the plurality of digital jitter measurements.

In several embodiments, the method further includes using the digital signal processing circuit to compare the estimate of the jitter of the test clock signal to a reference jitter threshold. According to a number of embodiments, the method further includes using the digital signal processing circuit to generate the reference jitter threshold from a plurality of digital reference jitter measurements obtained from an input clock signal of a known jitter.

In some embodiments, the jitter measuring circuit and the phase-locked loop are implemented on a common semiconductor chip. According to a number of embodiments, the phase-locked loop includes a time-stamper including the analog-to-digital converter. In accordance with several embodiments, the time-stamper is operable in a first mode in which the analog-to-digital converter outputs digital data for generating digital time stamps, and a second mode in which the analog-to-digital converter outputs the plurality of digital jitter measurements for jitter testing.

In various embodiments, the analog-to-digital converter includes a differential voltage input and the jitter measuring circuit includes a single-ended voltage output, the method further including using a single-ended to differential voltage buffer to provide single-ended to differential voltage conversion between the single-ended voltage output and the differential voltage input.

In various embodiments, the jitter measuring circuit includes a capacitor electrically connected between a sampling node and a first reference voltage, a buffer, and a sampling switch controlled by the test clock signal and electrically connected between the sampling node and an input to the buffer. According to a number of embodiments, the jitter measuring circuit further includes a resistor electrically connected between the sampling node and a second reference voltage. In accordance with several embodiments, the jitter measuring circuit further includes a current source electrically connected between the sampling node and a second reference voltage. According to some embodiments, the jitter measuring circuit further includes a reset switch electrically connected between the sampling node and the first reference voltage.

In certain embodiments, the present disclosure relates to a semiconductor chip including a phase-locked loop configured to generate a test clock signal, the phase-locked loop including a time-stamper that includes an analog-to-digital converter. The semiconductor chip further includes a jitter measuring circuit configured to obtain a plurality of analog jitter measurements of the test clock signal of the phase-locked loop, the analog-to-digital converter configured to convert the plurality of analog jitter measurements to a plurality of digital jitter measurements for estimating a jitter of the test clock signal.

In some embodiments, the jitter measuring circuit includes a capacitor electrically connected between an output node and a first reference voltage, a reference clock voltage-controlled current source controlled by a reference clock signal, and a test clock switch controlled by the test clock signal, the test clock switch and the voltage-controlled current source electrically connected in series between the output node and the first reference voltage. According to a number of embodiments, an output voltage at the output node generates a jitter measurement voltage proportional to a phase difference between the test clock signal and the reference clock signal. In accordance with several embodiments, the jitter measuring circuit further includes a ramp control circuit configured to control a slew of the reference clock signal based on a slew control signal. According to various embodiments, the ramp control signal is operable in a low gain mode associated with locking the phase-locked loop and a high gain mode associated with obtaining the plurality of analog jitter measurements of the test clock signal. In accordance with a number of embodiments, the jitter measuring circuit further includes a reset switch electrically connected between a second reference voltage and the output node. According to several embodiments, the reference clock voltage-controlled current source includes a first n-type metal-oxide-semiconductor transistor, the test clock switch includes a second n-type metal-oxide-semiconductor transistor, and the reset switch includes a p-type metal-oxide-semiconductor transistor.

In various embodiments, the semiconductor chip further includes a digital signal processing circuit configured to process the plurality of digital jitter measurements to estimate the jitter of the test clock signal. According to a number of embodiments, the digital signal processing circuit is configured to estimate the jitter of the test clock signal based on one or more statistical calculations on the plurality of digital jitter measurements. In accordance with several embodiments, the digital signal processing circuit is configured to estimate the jitter of the test clock signal based on a first derivative of the plurality of digital jitter measurements. According to some embodiments, the digital signal processing circuit is further configured to estimate the jitter of the test clock signal based on a standard deviation or variance of the first derivative of the plurality of digital jitter measurements. In accordance with a number of embodiments, the digital signal processing circuit is configured to compare the estimate of the jitter of the test clock signal to a reference jitter threshold. According to several embodiments, the digital signal processing circuit is further configured to generate the reference jitter threshold from a plurality of digital reference jitter measurements obtained from an input clock signal of a known jitter.

In some embodiments, the time-stamper is operable in a first mode in which the analog-to-digital converter outputs digital data for generating digital time stamps, and a second mode in which the analog-to-digital converter outputs the plurality of digital jitter measurements for jitter testing.

In various embodiments, the time-stamper further includes a charge pump in cascade with the analog-to-digital converter.

In several embodiments, the analog-to-digital converter includes a differential voltage input and the jitter measuring circuit includes a single-ended voltage output, the semiconductor chip further including a single-ended to differential voltage buffer coupled between the single-ended voltage output and the differential voltage input.

In various embodiments, the jitter measuring circuit includes a capacitor electrically connected between a sampling node and a first reference voltage, a buffer, and a sampling switch controlled by the test clock signal and electrically connected between the sampling node and an input to the buffer. According to a number of embodiments, the jitter measuring circuit further includes a resistor electrically connected between the sampling node and a second reference voltage. In accordance with several embodiments, the jitter measuring circuit further includes a current source electrically connected between the sampling node and a second reference voltage. According to some embodiments, the jitter measuring circuit further includes a reset switch electrically connected between the sampling node and the first reference voltage.

### BRIEF DESCRIPTION OF THE DRAWINGS

Embodiments of this disclosure will now be described, by way of non-limiting example, with reference to the accompanying drawings.

FIG. 1 is a schematic diagram of one embodiment of a phase-locked loop (PLL).

FIG. 2A is a schematic diagram of one embodiment of a time-stamper operating in a first mode in which a jitter measuring circuit is bypassed.

FIG. 2B is a schematic diagram of the time-stamper of FIG. 2A operating in a second mode in which the jitter measuring circuit measures clock signal jitter.

FIG. 3 is one example of a sub-sampling timing diagram for jitter measuring.

FIG. 4A is a schematic diagram of one embodiment of a jitter measuring circuit.

FIG. 4B is one example of a timing diagram for the jitter measuring circuit of FIG. 4A.

FIG. 5A is a block diagram of one embodiment of a jitter in self-test (JIST) digital signal processing (DSP) circuit.

FIG. 5B is one example of a graph of a measurement output of the JIST DSP circuit of FIG. 5A as accumulated jitter samples increase.

FIG. 6A is a flow chart of one embodiment of a method of generating a reference jitter threshold for jitter screening.

FIG. 6B is a flow chart of one embodiment of a method of jitter screening using a reference jitter threshold.

FIG. 6C is a flow chart of one embodiment of a method of estimating jitter.

FIG. 6D is a graph of two examples of probability distribution functions (PDFs) of jitter for the method of FIG. 6C.

FIG. 7 is a schematic diagram of another embodiment of a jitter measuring circuit.

FIG. 8A is a schematic diagram of one embodiment of a driver circuit for a jitter measuring circuit.

FIG. 8B is one example of a timing diagram for the driver circuit of FIG. 8A.

FIG. 9A is a schematic diagram of one embodiment of a ramp control circuit for a jitter measuring circuit.

FIG. 9B is a schematic diagram of one embodiment of a reference voltage generation circuit for the ramp control circuit of FIG. 9B.

FIG. 9C is a graph of one example of a slew-controlled reference clock signal versus slew control setting in low gain mode for the ramp control circuit of FIG. 9A.

FIG. 9D is a graph of one example of a slew-controlled reference clock signal versus slew control setting in high gain mode for the ramp control circuit of FIG. 9A.

FIG. 10A is a graph of differential output voltage of a jitter measuring circuit versus clock delay for a low gain mode/low slew control setting.

FIG. 10B is a graph of differential output voltage of a jitter measuring circuit versus clock delay for various slew control settings in a low gain mode.

FIG. 11A is a graph of differential output voltage of a jitter measuring circuit versus clock delay for a high gain mode.

FIG. 11B is a graph of differential output voltage of a jitter measuring circuit versus clock delay for various slew control settings in a high gain mode.

FIG. 12A is a schematic diagram of another embodiment of a jitter measuring circuit.

FIG. 12B is a schematic diagram of another embodiment of a jitter measuring circuit.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The performance of certain electronic systems is limited by jitter of a clock signal generated by a phase-locked loop (PLL). For example, a PLL's clock signal can be used in a high-speed telecommunication system for sampling, and the jitter of the clock signal can limit overall system performance.

A PLL can be specified to operate with jitter that is less than a certain jitter threshold, for instance, less than 100 fs, root mean square (rms) over a 12 kHz - 20 MHz frequency band. By specifying the PLL to operate with a certain jitter tolerance, a desired overall system performance can be achieved.

However, it can be challenging to screen parts that exceed the jitter threshold in a production test environment.

In one example, expensive phase noise analyzers (for instance, an E5052B phase noise analyzer instrument) can be used to test each PLL-based part for compliance with the jitter threshold. However, such an approach is time consuming and/or costly since it can take several seconds per part to provide accurate jitter screening using a phase noise analyzer. In another example, digital signal processing (DSP) algorithms can be used to process the PLL's clock zero-crossings. However, such an approach provides insufficient resolution (for instance, ˜16 ps of resolution or poorer) relative to jitter (for instance, in the range of +/−2 ps peak-to-peak (pk-pk)).

Apparatus and methods for jitter testing of clock signals are disclosed. In certain embodiments, a jitter measuring circuit is used to obtain jitter measurements of a PLL's clock signal in an analog domain. For example, the analog jitter measurements can be generated by discharging a capacitor to a voltage that is proportional to a phase difference between a test clock signal from the PLL and a reference clock signal that can be assumed to be ideal. Additionally, the analog jitter measurements are digitized and processed (for instance, using digital signal processing) to generate an estimate of jitter.

In some implementations, a jitter measuring circuit can be implemented on-chip with one or more PLLs to provide jitter screening. Additionally, the jitter measuring circuit can utilize existing components of a PLL, such as an analog-to-digital converter (ADC) that is part of a time-stamper of the PLL, to aid in processing the jitter measurements. Thus, a compact and efficient solution for jitter measurement is achieved.

Furthermore, by integrating the jitter measurement on-chip, a need for expensive test equipment, such as an E5052B phase noise analyzer instrument, is avoided. Moreover, obtaining jitter samples in the analog domain prior to digitization ensures that jitter measurement accuracy is not limited by a time-stamper resolution. Furthermore, such jitter measurement techniques allow for simultaneous jitter measurements across multiple PLLs under test, thereby significantly reducing test time and increasing production test throughput.

The jitter measurements can be processed in a variety of ways to obtain the estimate of jitter. In one example, the jitter measurements are assumed to be random with a Gaussian distribution, and a standard deviation of a first derivative of the jitter measurements provides an estimate of jitter on the test clock signal from the PLL.

Accordingly, aspects of the present disclosure provide on-chip jitter measurement for PLLs and/or DSP algorithms suitable for estimating jitter from the jitter measurements. Such techniques can be used to screen PLL-based parts for jitter relative to a jitter threshold. Furthermore, the on-chip measurement circuits can measure jitter with high resolution, for instance, 1 ps, pk-pk for 75 fs, rms in 12 kHz-20 MHz band or finer resolution.

Although the jitter measuring schemes herein are suitable for on-chip self-test of PLLs, the teachings herein are also applicable to implementations in which the jitter measuring circuit is on a separate chip as the PLL. In such implementations, the jitter measuring chip with the jitter measuring circuit can be used to provide jitter screening to PLL-based parts under test. For example, such a jitter measuring chip can be included as part of a production test board used for testing PLL-based parts for jitter screening. Accordingly, the embodiments herein are applicable to both on-chip jitter testing as well as to production test environments using multiple chips.

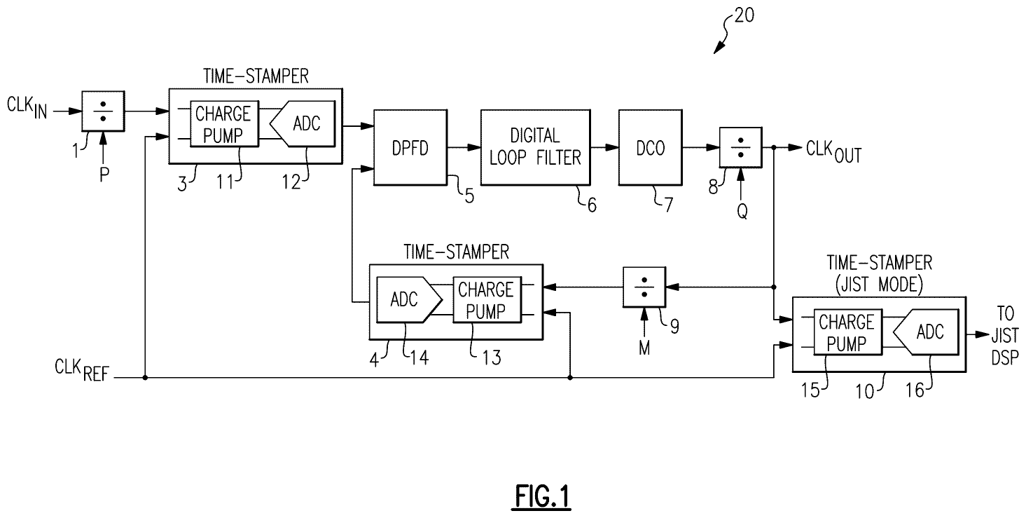

FIG. 1 is a schematic diagram of one embodiment of a PLL 20. The PLL 20 includes an input clock divider 1 (with divisor P), an input time-stamper 3, a digital phase-frequency detector (DPFD) 5, a digital loop filter 6, a digitally controlled oscillator (DCO) 7, an output divider 8 (with divisor Q), a feedback divider 9 (with divisor M), a feedback time-stamper 4, and an output time-stamper 10. As shown in FIG. 1, the input time-stamper 3 includes a charge pump 11 and an analog-to-digital converter (ADC) 12, while the feedback time-stamper 4 includes a charge pump 13 and an ADC 14. Additionally, the output time-stamper 10 includes a charge pump 15 and an ADC 16.

The PLL 20 of FIG. 1 depicts one example of a PLL that can be tested using the jitter measurement schemes herein. Further, the PLL 20 of FIG. 1 depicts one example of a PLL in which components of the PLL, such as the ADC 16 of the output time-stamper 10, can be re-used when obtaining jitter measurements to provide a compact circuit solution for jitter testing. Although the PLL 20 of FIG. 1 depicts one example of a PLL that can be utilized in this manner, the teachings herein can be used in conjunction with a wide variety of types of PLLs. Accordingly, other implementations of PLLs are possible.

The PLL 20 serves to generate an output clock signal CLK_{OUT} having a controlled phase and frequency relationship with respect to the input clock signal CLK_{IN}. For example, the value of the divisors P/Q/M can be selected to achieve a desired frequency ratio between the output clock signal CLK_{OUT} and the input clock signal CLK_{IN}. Furthermore, the depicted control loop of the PLL 20 can operate to lock the phase of the output clock signal CLK_{OUT} relative to the phase of the input clock signal CLK_{IN}, with or without a phase offset as desired for a particular application.

In the illustrated embodiment, the input clock divider 1 divides an input clock signal CLK_{IN} by the divisor P to generate a divided input clock signal that is provided to the input time-stamper 3. The input time-stamper 3 also receives a reference clock signal CLK_{REF}, which is used as a time reference for digitally time-stamping the divided input clock signal. For example, the input time-stamper 3 can serve to generate digital time stamps representing time instances at which transitions (for instance, rising and/or falling edges) of the divided input clock signal occur. Additionally, such digital time stamps can be obtained using the reference clock signal CLK_{REF} as the time base or reference for stamping.

The input time-stamper 3 of FIG. 1 includes a cascade of the charge pump 11 and the ADC 12. The input time-stamper 3 can operate using a two-step conversion including a first step in which the charge pump 11 generates charge pump currents in response to input clock signal edges and a second step in which the ADC 12 measures a change in capacitor voltage arising from the charge pump currents. Additionally, the ADC's digital output can be processed to generate digital time stamps indicating the timing of the input clock signal's transitions. In certain implementations, the ADC 12 is implemented as a successive-approximate-register (SAR) ADC. Although one implementation of a time-stamper is shown, time-stampers can be implemented in other ways.

With continuing reference to FIG. 1, the DPFD 5 compares the digital time stamps from the input time-stamper 3 to digital time stamps from the feedback time-stamper 4 to generate a phase and frequency detection signal that indicates whether the edges of the input clock signal lag or lead the feedback clock signal. The phase and frequency detection signal from the DPFD 5 is provided to the digital loop filter 6, which digitally filters the phase and frequency detection signal to generate a digital oscillator control signal that controls a frequency of oscillation of the DCO 7. The digital loop filter 6 can be implemented to achieve a desired loop stability and/or bandwidth of the PLL 20.

In the illustrated embodiment, the DCO 7 outputs an oscillator clock signal, which is divided by the output clock divider 8 to generate an output clock signal CLK_{OUT} of the PLL 20. The frequency of oscillation of the DCO 7 is set by the digital oscillator control signal from the loop filter 6.

With continuing reference to FIG. 1, the feedback divider 9 divides the output clock signal CLK_{OUT} to generate a feedback clock signal that is provided as in input to the time-stamper 4. The feedback time-stamper 4 also receives the reference clock signal CLK_{REF}, which is used as a time reference for digitally time-stamping the feedback clock signal. Thus, the feedback time-stamper 4 generates digital time stamps representing time instances at which transitions of the feedback clock signal occur, with the reference clock signal CLK_{REF} serving as the time base for stamping. The feedback time-stamper 4 of FIG. 1 includes a cascade of the charge pump 13 and the ADC 14.

The output clock signal CLK_{OUT} of the PLL 20 can be provided to one or more downstream circuits with or without subsequent division, buffering, and/or other processing. The jitter of the output clock signal CLK_{OUT} impacts the performance of the downstream circuits. Thus, it is desirable to be able to screen the PLL 20 for jitter of the output clock signal CLK_{OUT} to ensure that the PLL 20 operates within a desired jitter tolerance.

As shown in FIG. 1, the output time-stamper 10 receives the output clock signal CLK_{OUT} and the reference clock signal CLK_{REF}, which serves as a time reference for digitally time-stamping the output clock signal CLK_{OUT}. Thus, the output time-stamper 10 generates digital time stamps representing time instances at which transitions of the output clock signal CLK_{OUT} occur, with the reference clock signal CLK_{REF} serving as the time base for stamping. The output time-stamper 10 of FIG. 1 includes a cascade of the charge pump 15 and the ADC 16.

In certain embodiments herein, a time-stamper of a PLL is implemented with a jitter measuring circuit for measuring the jitter of the PLL's output clock signal during a jitter self-test mode. For instance, in the example of FIG. 1, the output time-stamper 10 can be implemented with a jitter measuring circuit that measures a jitter of the PLL's output clock signal in self-test. For example, in certain implementations, the output time-stamper 10 can be operated in a time-stamping mode in which the output time-stamper 10 generates digital time stamps of the output clock signal CLK_{OUT}, or in a jitter test mode in which the jitter measuring circuit generates analog jitter measurements that are digitized by the ADC 16. In the jitter test mode, the digital representations of the jitter measurements can be provided to a JIST DSP for processing to estimate the jitter.

Such jitter measurement can be direct (for instance, by multiplexing the output clock signal CLK_{OUT} to an input of the jitter measuring circuit during self-test after the PLL has been locked) or indirect by measuring another clock signal indicative of the jitter of the output clock signal CLK_{OUT}. For example, since the feedback clock signal corresponds to a divided version of the output clock signal CLK_{OUT}, an amount of jitter of the feedback clock signal can correspond to an estimate of the jitter of the PLL's output clock signal.

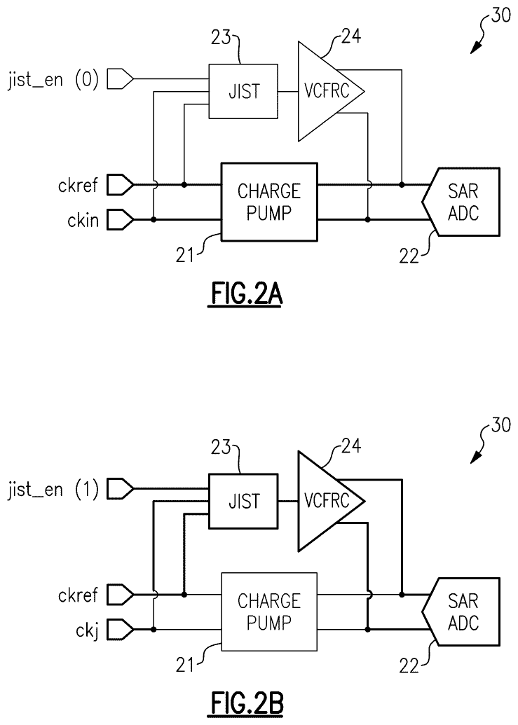

FIG. 2A is a schematic diagram of one embodiment of a time-stamper 30 operating in a first mode in which a jitter measuring circuit is bypassed. FIG. 2B is a schematic diagram of the time-stamper 30 of FIG. 2A operating in a second mode in which the jitter measuring circuit measures clock signal jitter. The time-stamper 30 includes a charge pump 21, a SAR ADC 22, a jitter measuring circuit 23, and a single-ended to differential buffer 24.

With reference to FIGS. 2A and 2B the time-stamper 30 can serve as a time-stamper included in a PLL. For instance, the time-stamper 30 can correspond to one implementation of the output time-stamper 10 of the PLL 20 of FIG. 1.

The time-stamper 30 of FIGS. 2A and 2B is operable in multiple modes, including the first mode shown in FIG. 2A in which the time-stamper 30 digitally time stamps a clock signal ckin based on timing of a reference clock signal ckref. In this example, the first mode is indicated by a JIST enable signal jist_en having a low state (0), while the second mode is indicated by the JIST enable signal jist_en having a high state (1).

When operating in the first mode, the SAR ADC 22 outputs digital data used to generate time stamps representing a timing of transitions of the clock signal ckin.

With continuing reference to FIGS. 2A and 2B, the time-stamper 30 is also operable in the second mode in which a test clock signal ckj is provided to the jitter measuring circuit 23, which generates analog jitter measurements that serve as samples of the test clock signal's jitter. In certain implementations, a multiplexer is included to select a particular clock signal to provide as input to the time-stamper 30. In this example, the analog jitter measurement from the jitter measuring circuit 23 is a single-ended voltage, which is converted by the single-ended to differential buffer 24 to a differential jitter measurement voltage that is digitized by the SAR ADC 22. When providing self-testing in this manner, the digitized jitter measurements can be provided by the SAR ADC 22 to a JIST DSP block to determine an overall estimate of the jitter of the test clock signal ckj.

The time-stamper 30 of FIGS. 2A and 2B advantageously re-uses the SAR ADC 22 to both provide time-stamping during normal operation of the PLL and to provide analog-to-digital conversion of jitter measurements during jitter self-testing. By implementing a PLL in this manner, a compact and/or low-cost solution for jitter screening is provided.

In certain implementations, a PLL (for example, the PLL 20 of FIG. 1) is initially locked. After the PLL is locked, the time-stamper (for example, the time-stamper 10 of FIG. 1) can be transitioned to the second mode in which jitter measurements of the PLL's output clock signal are obtained. To enhance the accuracy of the jitter measurements, in certain implementations the PLL is locked with a desired phase offset prior to measuring the PLL's jitter.

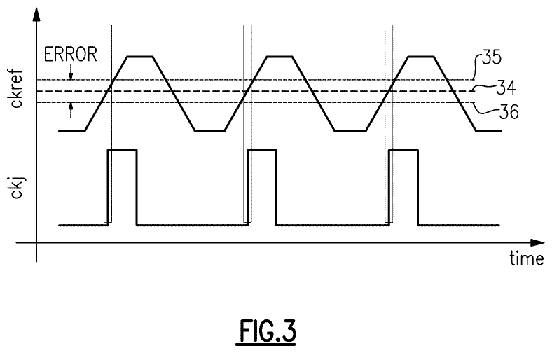

FIG. 3 is one example of a sub-sampling timing diagram for jitter measuring. In this example, a timing diagram of a reference clock signal ckref is shown relative to a test clock signal ckj for which jitter is being measured. The reference clock signal ckref has low jitter and thus is considered approximately ideal.

In certain embodiments herein, jitter measuring is performed by sampling the reference clock signal ckref with the test clock signal ckj over N cycles, with a jitter measuring circuit capturing the change in sampled voltage for each cycle. Additionally, the jitter samples captured over the N cycles can be processed using DSP to determine an estimate of jitter.

For example, in the absence of jitter, sampling should occur at voltage 34, but jitter can lead to sampling at voltages 35/36. Thus, the difference in the voltages 35/36 corresponds to an error arising from jitter in the test clock signal ckj. By observing the change in sampled voltage over the N cycles, an estimate of the jitter can be obtained.

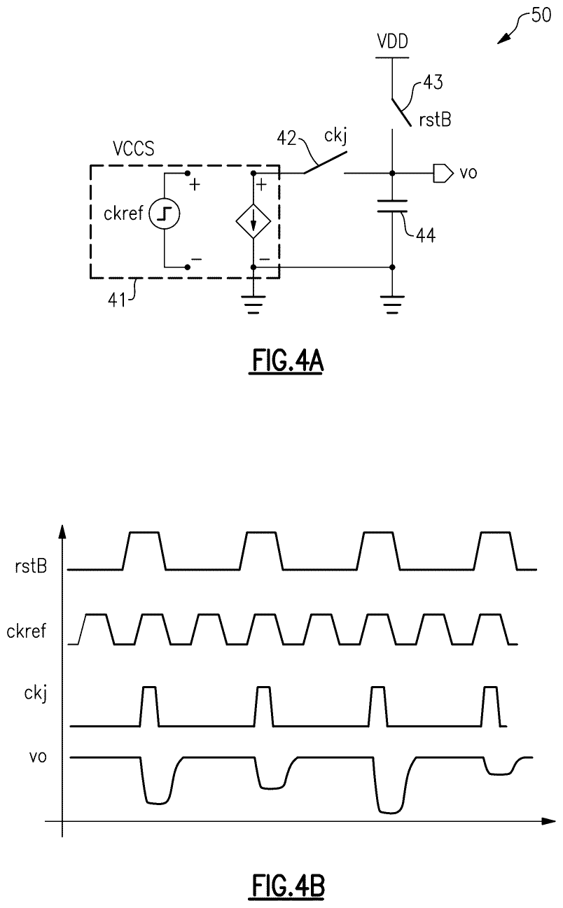

FIG. 4A is a schematic diagram of one embodiment of a jitter measuring circuit 50. The jitter measuring circuit 50 includes a reference clock voltage-controlled current-source (VCCS) 41, a test clock switch 42, a reset switch 43, and a capacitor 44. FIG. 4B is one example of a timing diagram for the jitter measuring circuit 50 of FIG. 4A.

The jitter measuring circuit 50 depicts one example of a jitter measuring circuit suitable for obtaining jitter measurements from a test clock signal from a PLL. Although the jitter measuring circuit 50 depicts one example of a suitable jitter measuring circuit, the teachings herein are applicable to jitter measuring circuits implemented in other ways. Accordingly, other implementations are possible.

In certain embodiments, a jitter measuring circuit (such as the jitter measuring circuit 50 of FIG. 4A) is implemented on-chip with a PLL that is under test. Thus, the jitter measuring circuit and the PLL can be implemented on a common semiconductor chip. In some implementations, the common semiconductor chip also includes an ADC and/or a DSP processing circuit for processing the jitter measurements.

With reference to FIGS. 4A and 4B, the reference clock VCCS 41 and the test clock switch 42 are electrically connected in series between a first reference voltage (corresponding to a ground voltage, in this example) and an output node that provides an analog measurement output voltage vo. The VCCS 41 generates a current that is controlled based on a voltage of a reference clock signal ckref, and the current flows through the test clock switch 42 to the capacitor 44 when the test clock switch 42 is turned on. Additionally, the reset switch 43 is electrically connected between a second reference voltage (corresponding to a supply voltage VDD, in this example) and the output node, and the output capacitor 44 is electrically connected between the output node and the ground voltage.

In the illustrated embodiment, the reference clock VCCS 41 generates a current that is controlled by a reference clock signal that can be approximated as ideal. Additionally, the test clock switch 42 is controlled by a test clock signal (corresponding to the test clock signal for which jitter is being measured), while the reset switch 43 is controlled by an inverted reset control signal rstB.

In certain implementations, the reference clock VCCS 41, the test clock switch 42, and the reset switch 43 are implemented using field-effect transistors (FETs), such as metal-oxide semiconductor (MOS) transistors. For instance, in one example, the reference clock VCCS 41 and the test clock switch 42 are implemented as n-type MOS (NMOS) transistors while the reset switch 43 is implemented as a p-type MOS (PMOS) transistor.

With continuing reference to FIGS. 4A and 4B, the jitter measuring circuit 50 operates by initially charging the voltage of the capacitor 44 to the supply voltage VDD by turning on the reset switch 43 using the inverted reset control signal rstB. After the reset switch 43 is turned off, the jitter measuring circuit 50 generates the jitter measurement by discharging the capacitor 44 to an output voltage vo that is proportional to a phase difference between the test clock signal ckj and the reference clock signal ckref.

One example of waveforms for the inverted reset control signal rstB, the reference clock signal ckref, the test clock signal ckj, and the output voltage vo are shown in FIG. 4B.

As described earlier, the analog measurement output voltage vo can be digitized using an ADC to generate digital jitter samples that can be subsequently processed to generate an estimate of jitter. For example, the analog measurement output voltage vo can be buffered (for instance, using the single-ended to differential voltage buffer 24 shown in the embodiments of FIGS. 2A and 2B) and subsequently digitized using an ADC (for instance, using the SAR ADC 22 shown in the embodiments of FIGS. 2A and 2B).

The digitized jitter samples can be processed using a wide variety of digital processing algorithms to generate the estimate of jitter. In one example, jitter is assumed to be random with a Gaussian distribution, and a standard deviation or variance of a first derivative of the digitized jitter samples provides an estimate of jitter on the test clock signal.

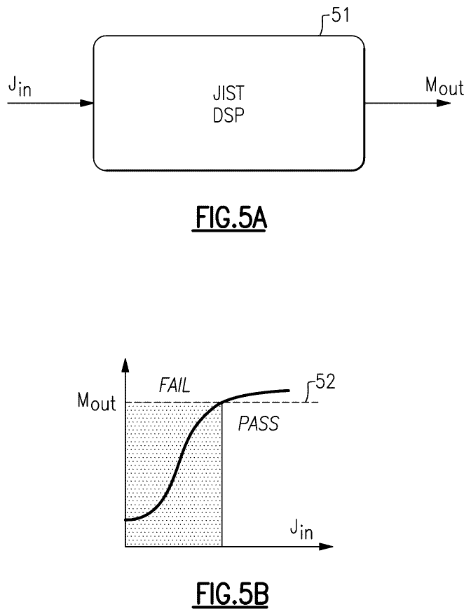

FIG. 5A is a block diagram of one embodiment of a JIST digital signal processing (DSP) circuit 51. FIG. 5B is one example of a graph of a measurement output Mₒᵤₜ of the JIST DSP circuit 51 of FIG. 5A as accumulated jitter samples Jᵢₙ increase.

With reference to FIGS. 5A and 5B, the JIST DSP circuit 51 receives the digitized jitter samples Jᵢₙ, which are processed to generate the digital measurement output Mₒᵤₜ indicating if the estimated jitter satisfies a jitter threshold 52. The digitized jitter samples Jᵢₙ are received from an ADC that digitizes jitter measurements captured by a jitter measuring circuit. For example, the input of the JIST DSP circuit 51 can be coupled to an output of an ADC (for instance, to an output of the SAR ADC 22 of FIGS. 2A and 2B).

In the example of FIGS. 5A and 5B, the accuracy of the digital measurement output Mₒᵤₜ in estimating jitter increase as the number of accumulated jitter samples Jᵢₙ increases. For example, the JIST DSP circuit 51 can calculate a standard deviation of a first derivative of the digitized jitter samples Jᵢₙ to provide an estimate of jitter on the test clock signal, and the accuracy of the standard deviation measurement can improve as the number of samples increases.

In the example of FIG. 5B, after a sufficient number of the jitter samples Jᵢₙ are processed the JIST DSP circuit 51 determines that the standard deviation is too large and thus that the test clock signal has failed the jitter test by exceeding the jitter threshold 52.

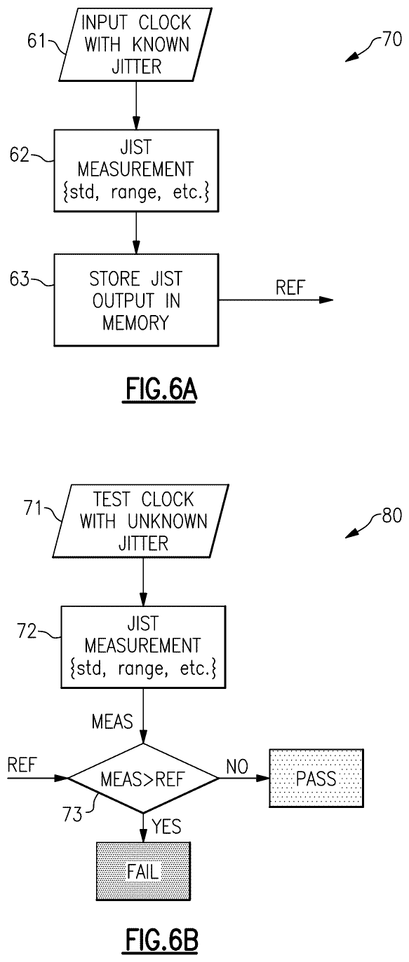

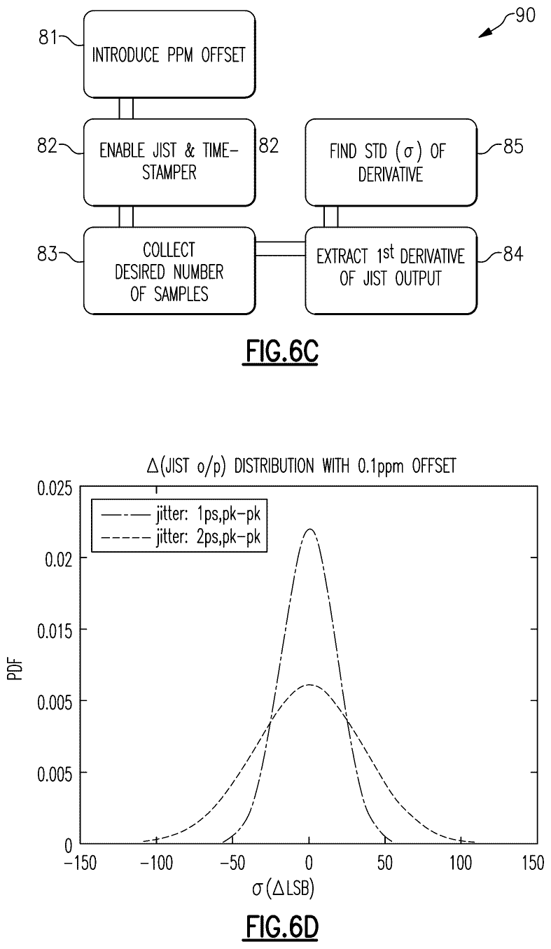

FIG. 6A is a flow chart of one embodiment of a method 70 of generating a reference jitter threshold for jitter screening. The method 70 can be implemented by a JIST DSP circuit, such as the JIST DSP circuit 51 of FIG. 5A.

In the illustrated embodiment, the method 70 begins at a block 61 in which jitter samples for an input clock signal with a known jitter is provided to the JIST DSP circuit. In an ensuing block 62, the JIST DSP circuit performs various statistical calculations on the jitter samples, such as standard deviation (or variance), range, and/or any other suitable statistical calculations to generate a digital measurement output of the JIST DSP circuit. In an ensuing block 63, the digital measurement output of the JIST is stored in memory. The stored digital measurement output can serve as a reference jitter threshold REF, such as the jitter threshold 52 of FIG. 5B.

FIG. 6B is a flow chart of one embodiment of a method 80 of jitter screening using a reference jitter threshold REF. The method 80 can be implemented by a JIST DSP circuit, such as the JIST DSP circuit 51 of FIG. 5A.

In the illustrated embodiment, the method 80 begins at a block 71 in which jitter samples for a test clock signal with an unknown jitter is provided to the JIST DSP circuit. In an ensuing block 72, the JIST DSP circuit performs various statistical calculations on the jitter samples, such as standard deviation, range, and/or any other suitable statistical calculations to generate a digital measurement output of the JIST DSP circuit. In an ensuing decision block 73, the digital measurement output of the JIST DSP circuit is compared to the reference jitter threshold REF to determine whether the test clock signal of the PLL has passed or failed the jitter test. For instance, in this example, the PLL fails the jitter test when the digital measurement output of the JIST DSP circuit exceeds the reference jitter threshold REF and passes the jitter test when the digital measurement output of the JIST DSP circuit is less than or equal to the reference jitter threshold REF.

FIG. 6C is a flow chart of one embodiment of a method 90 of estimating jitter. The method 90 can be implemented by a jitter measuring circuit (such as the jitter measuring circuit 23 implemented as part of the time-stamper 30 of FIGS. 2A and 2B) that provides digitized jitter samples to a JIST DSP circuit (such as the JIST DSP circuit 51 of FIG. 5A).

In the illustrated embodiment, the method 90 begins at a block 81 in which a desired timing offset is introduced. For example, the timing offset can be in parts per million (ppm). The timing offset can aid in positioning the edges of a test clock signal relative to the edges of a reference clock signal (see, for example, FIG. 3) as desired to accurately measure jitter. In an ensuing block 82, the jitter measuring circuit and time-stamper are enabled as part of a jitter measurement mode for JIST. In an ensuing block 83, the JIST DSP circuit collects a desired number of digitized jitter samples. In an ensuing block 84, a first derivative of the digitized jitter samples is determined. In an ensuing block 85, a standard deviation (σ) or variance of the first derivative is determined by the JIST DSP circuit. The resulting output of the JIST DSP circuit can be compared to a jitter threshold to determine whether the test clock signal from the PLL has passed the jitter screening.

FIG. 6D is a graph of two examples of probability distribution functions (PDFs) of jitter for the method of FIG. 6C. The graph includes a first PDF for a 1 ps pk-pk jitter and a second PDF for a 2 ps pk-pk jitter. The PDFs are depicted for an example with a 0.1 ppm offset.

As shown in FIG. 6D, the standard deviation of the first derivative of the digitized jitter samples serves to indicate the amount of pk-pk jitter. For example, the first PDF associated with 1 ps pk-pk jitter has a small standard deviation relative to the second PDF associated with 2 ps pk-pk jitter.

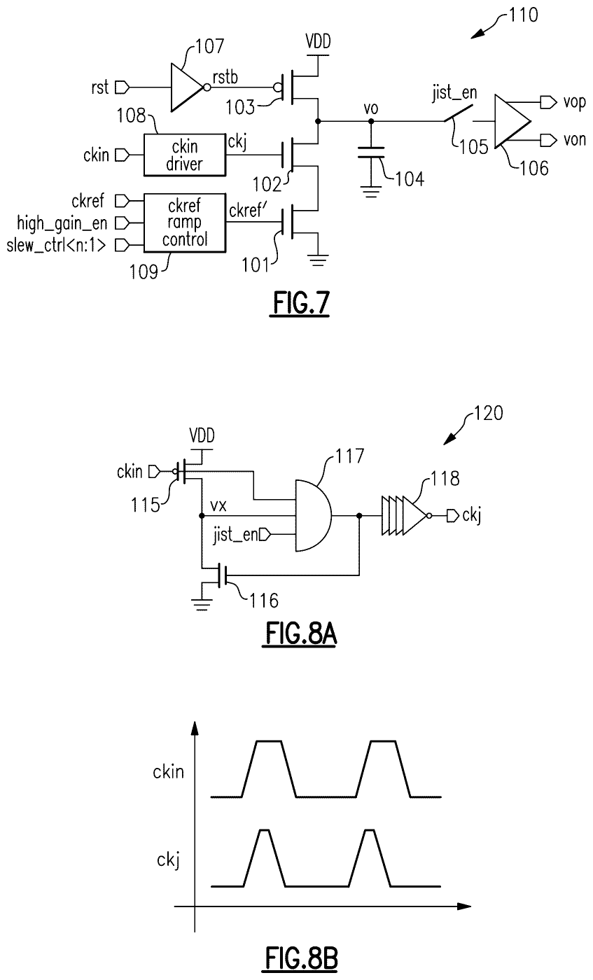

FIG. 7 is a schematic diagram of another embodiment of a jitter measuring circuit 110. The jitter measuring circuit 110 includes a reference clock NMOS transistor 101, a test clock NMOS transistor 102, a reset PMOS transistor 103, a capacitor 104, an JIST enable switch 105, a single-ended to differential output buffer 106, a reset inverter 107, a test clock driver 108, and a reference clock ramp control circuit 109.

As shown in FIG. 7, the reset inverter 107 inverts a reset control signal rst to generate an inverted reset control signal rstb that is provided to a gate of the reset PMOS transistor 103. The reset PMOS transistor 103 is electrically connected between a supply voltage VDD and an output node that provides analog measurement output voltage vo.

In the illustrated embodiment, the test clock driver 108 receives an input clock signal ckin and provides a gate of the test clock NMOS transistor 102 with a test clock signal ckj for jitter testing. Furthermore, a gate of the reference clock NMOS transistor 101 receives a slew-controlled reference clock signal ckref′ from the reference clock ramp control circuit 109. The reference clock NMOS transistor 101 and the test clock NMOS transistor 102 are electrically connected in series between a ground voltage and the output node, while the capacitor 104 is electrically connected between the output node and the ground voltage.

The jitter measuring circuit 110 of FIG. 7 operates in a manner similar to that of the jitter measuring circuit 50 of FIG. 4A. For example, the jitter measuring circuit 110 operates by initially charging the voltage of the capacitor 104 to the supply voltage VDD by turning on the reset PMOS transistor 103 using the inverted reset control signal rstB. After the reset PMOS transistor 103 is turned off, the jitter measuring circuit 110 generates the jitter measurement by discharging the capacitor 104 to an output voltage vo that is proportional to a phase difference between the test clock signal ckj and the slew-controlled reference clock signal ckref′.

In the illustrated embodiment, the JIST enable switch 105 is electrically connected between the output node and an input of the single-ended to differential output buffer 106, and serves to provide the output voltage vo to the single-ended to differential output buffer 106 when in a JIST mode (as indicated by a jist_en signal controlling the JIST enable switch 105). Thus, when operating in the JIST mode, the single-ended to differential output buffer 106 outputs a differential output voltage vop/von, which can be provided to an ADC for digitization. For example, the single-ended to differential output buffer 106 can correspond to the single-ended to differential output buffer 24 of FIGS. 2A and 2B.

With continuing reference to FIG. 7, the jitter measuring circuit 110 includes the reference clock ramp control circuit 109, which provides a controllable amount of slew adjustment to the reference clock signal ckref to generate the slew-controlled reference clock signal ckref′. The amount of slew is controlled by the slew control signal slew_ctrl<n:1>, which is n-bit in this example. The slew control signal controls the slope of the edges of the slew-controlled reference clock signal ckref′, thereby controlling an amount of gain.

The reference clock ramp control circuit 109 is also selectively operable in a high gain mode using a high gain enable signal high_gain_en. For example, the high gain mode can be suitable for jitter measurement while the low gain mode can be suitable for edge alignment. Since JIST can rely on the PLL being locked, the low gain mode can be used for edge alignment while the high gain mode can thereafter be used for jitter measurement.

FIG. 8A is a schematic diagram of one embodiment of a driver circuit 120 for a jitter measuring circuit. The driver circuit 120 includes an input PMOS transistor 115, an AND gate 117, a chain of inverters 118, and a feedback NMOS transistor 116. The driver circuit 120 depicts one example of the driver circuit 108 of FIG. 7. However, other implementations of driver circuit are possible.

In the illustrated embodiment, the AND gate 117 includes a first input that receives a clock input signal ckin, a second input that receives a feedback signal vx from a feedback node, and a third input that receives a JIST enable signal jist_en. The output of the AND gate 117 is provided to an input of the chain of inverters 118, which generates the test clock signal ckj by buffering the output of the AND gate 117. The output of the AND gate 117 is also provided to the gate of the feedback NMOS transistor 116, which is electrically connected between the feedback node and a ground voltage. Additionally, the PMOS input transistor 115 is electrically connected between a supply voltage VDD and the feedback node, and a gate of the input PMOS transistor 115 receives the clock input signal ckin.

FIG. 8B is one example of a timing diagram for the driver circuit 120 of FIG. 8A. As shown in FIG. 8B, the driver circuit 120 serves to generate the test clock signal ckj with a reduced pulse width (and also a reduced duty cycle) relative to a pulse width of the input clock signal ckin. Reducing the pulse width of the test clock signal cjk can aid in providing a more accurate jitter measurement.

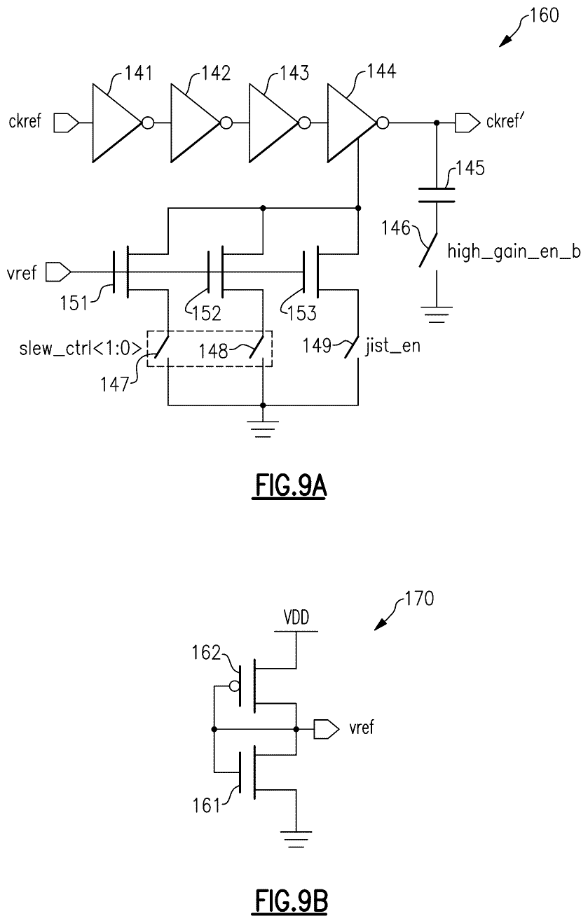

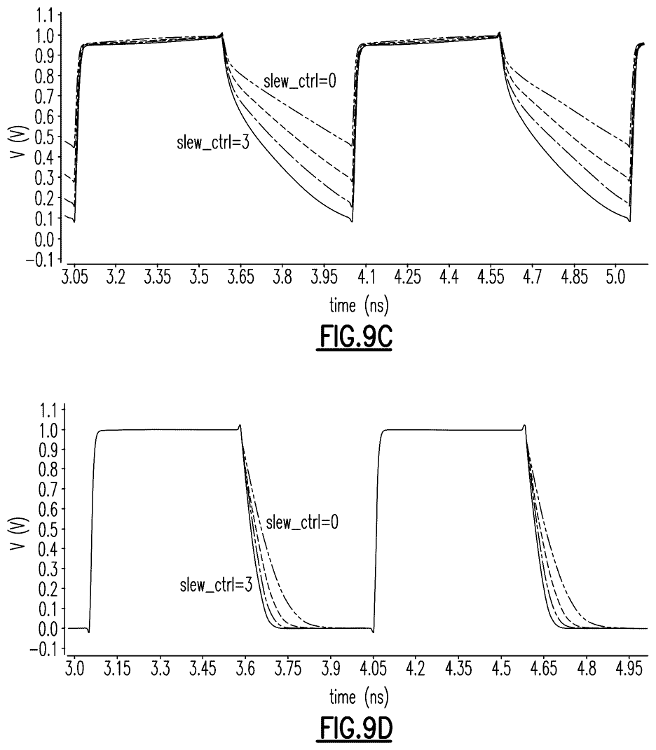

FIG. 9A is a schematic diagram of one embodiment of a ramp control circuit 160 for a jitter measuring circuit. The ramp control circuit 160 includes a first clock signal inverter 141, a second clock signal inverter 142, a third clock signal inverter 143, a fourth clock signal inverter 144, a capacitor 145, a high gain switch 146, a first slew control switch 147, a second slew control switch 148, a JIST enable switch 149, a first NMOS transistor 151, a second NMOS transistor 152, and a third NMOS transistor 153. The ramp control circuit 160 depicts one example of the ramp control circuit 109 of FIG. 7. However, other implementations of ramp control circuits are possible.

In the illustrated embodiment, the inverters 141-144 are connected in a chain, with the first inverter 141 having an input that receives the reference clock signal ckref and the fourth inverter 144 having an output the provides the slew-controlled reference clock signal clkref′.

As shown in FIG. 9A, a first end of the capacitor 145 is connected to the output of the fourth inverter 144, while a second end of the capacitor 145 is connected to a ground voltage through the high gain switch 146. When operating in a high gain mode (as indicated by a state of the inverted high gain enable signal high_gain_en_b), the high gain switch 146 is turned off to reduce the output capacitance. However, when operating in a low gain mode (as indicated by the state of the inverted high gain enable signal high_gain_en_b), the high gain switch 146 is turned on to increase the output capacitance.

In the illustrated embodiment, a pull-down drive strength of the fourth inverter 144 is controllable based on a slew control signal slew_ctl<1:0>, which is 2 bits in this example. For example, an NMOS transistor of the inverter 144 can be electrically connected to a ground voltage through the selectable circuit branches shown in FIG. 9A. The selectable circuit branches include a first circuit branch including the first slew control switch 147 and the first NMOS transistor 151 in series, a second circuit branch including the second slew control switch 148 and the NMOS transistor 152 in series, and a third circuit branch including the JIST enable switch 149 and the third NMOS transistor 153 in series.

Accordingly, each bit of the slew control signal slew_ctl<1:0> can selectively be enabled to activate a corresponding circuit branch and increase the pull-down strength of the fourth inverter 144. Additionally, when the ramp control circuit 160 is enabled (by a JIST enable signal jist_en that controls the JIST enable switch 149) a minimum pull-down strength is set by the third circuit branch. As shown in FIG. 9A, the gates of the NMOS transistors 151-153 are controlled by an analog reference voltage.

FIG. 9B is a schematic diagram of one embodiment of a reference voltage generation circuit 170 for the ramp control circuit 160 of FIG. 9B. The reference voltage generation circuit 170 includes an NMOS transistor 161 and a PMOS transistor 162 connected as inverter having an output connected back to an input. The resulting reference voltage vref is at a voltage level between that of the supply voltage VDD and the ground voltage of the inverter. Although one example of a reference voltage generation circuit for a ramp control circuit is shown, an analog reference voltage can be generated in other ways.

FIG. 9C is a graph of one example of a slew-controlled reference clock signal versus slew control setting in low gain mode for the ramp control circuit of FIG. 9A. As shown in FIG. 9C, the falling edge of the slew-controlled reference clock signal is controllable to one of multiple slew rates based on the slew control setting.

Although FIG. 9C depicts an example in which a slew of the falling edge of the slew-controlled reference clock signal is controllable, the teachings herein are also applicable to implementations in which a slew of the rising edge is controllable as well as to implementations in which the slew of the falling edge and rising edge are both controllable.

FIG. 9D is a graph of one example of a slew-controlled reference clock signal versus slew control setting in high gain mode for the ramp control circuit of FIG. 9A. As shown in FIG. 9D, the falling edge of the slew-controlled reference clock signal is controllable to one of multiple slew rates based on the slew control setting. Furthermore, as shown by a comparison of FIGS. 9C and 9D, an overall gain of the ramp control circuit is adjustable by setting the ramp control circuit in the high gain mode or the low gain mode.

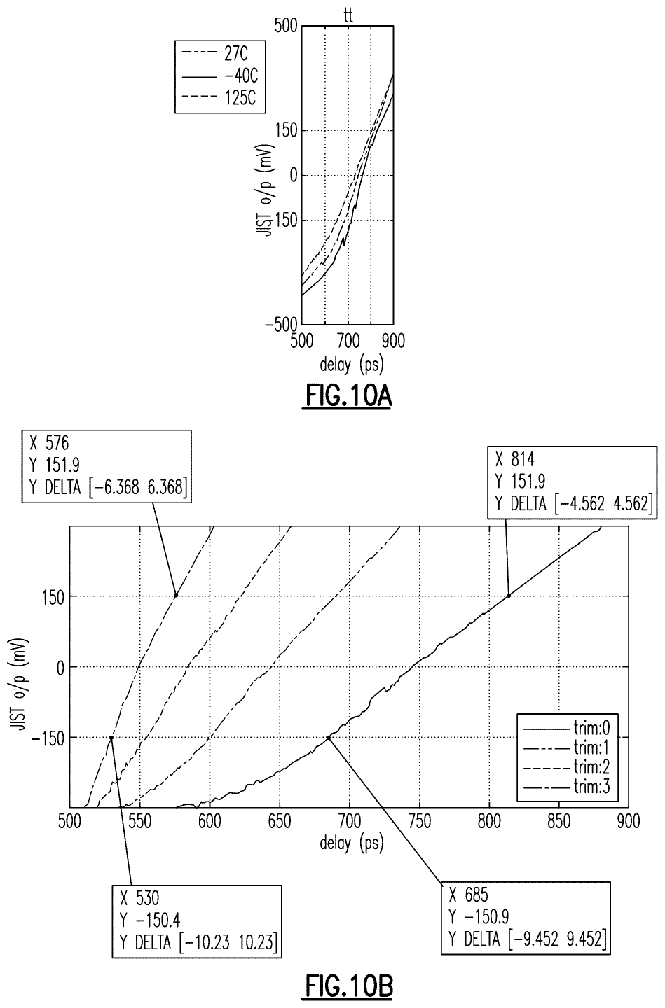

FIG. 10A is a graph of differential output voltage of a jitter measuring circuit versus clock delay for a low gain mode/low slew control setting. The graph depicts an example of how the differential output voltage responds to a delay between a test clock signal and a reference clock signal. The graph is depicted for an example in which the ramp control circuit operates at a typical-typical (TT) processing corner and is set in the low gain mode with the lowest slew control setting.

FIG. 10B is a graph of differential output voltage of a jitter measuring circuit versus clock delay for various slew control settings in a low gain mode. As shown in FIG. 10B, the slew control settings can be adjusted to achieve different response characteristics of differential output voltage versus delay between the test clock signal and the reference clock signal.

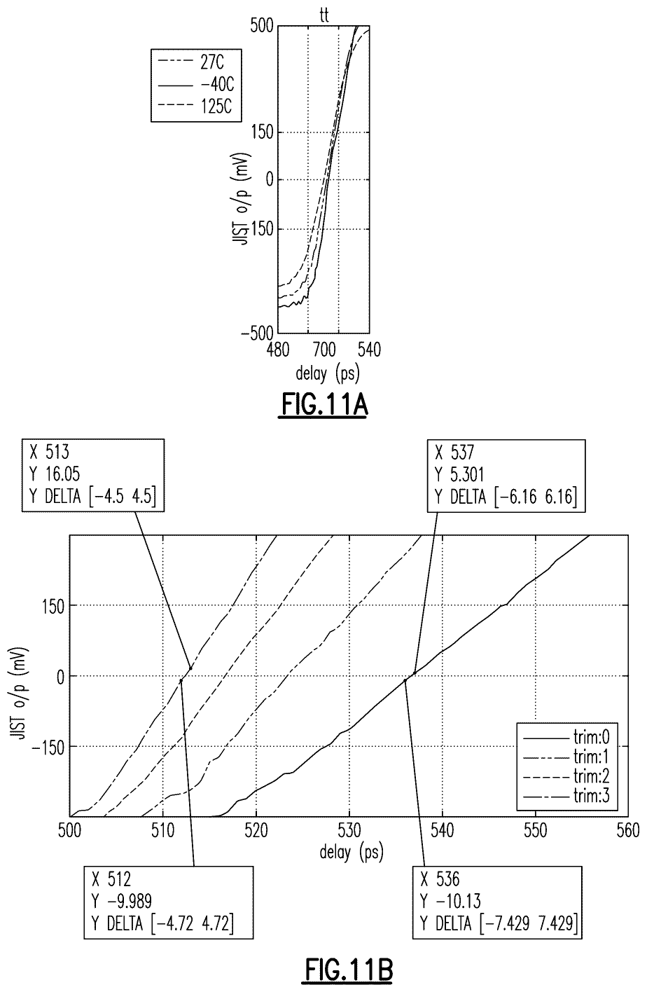

FIG. 11A is a graph of differential output voltage of a jitter measuring circuit versus clock delay for a high gain mode/high slew control setting. The graph depicts an example of how the differential output voltage responds to a delay between a test clock signal and a reference clock signal. The graph is depicted for an example in which the ramp control circuit operates at a TT processing corner and is set in the high gain mode with the highest slew control setting. As shown by a comparison of FIG. 11A and FIG. 10A, the jitter measuring circuit is more responsive to delay when operating in the high gain mode relative to the low gain mode.

FIG. 11B is a graph of differential output voltage of a jitter measuring circuit versus clock delay for various slew control settings in a high gain mode. As shown in FIG. 11B, the slew control settings can be adjusted to achieve different response characteristics of differential output voltage versus delay between the test clock signal and the reference clock signal. Furthermore, as shown by a comparison of FIG. 11B and FIG. 10B, the jitter measuring circuit is more responsive to delay when operating in the high gain mode relative to the low gain mode.

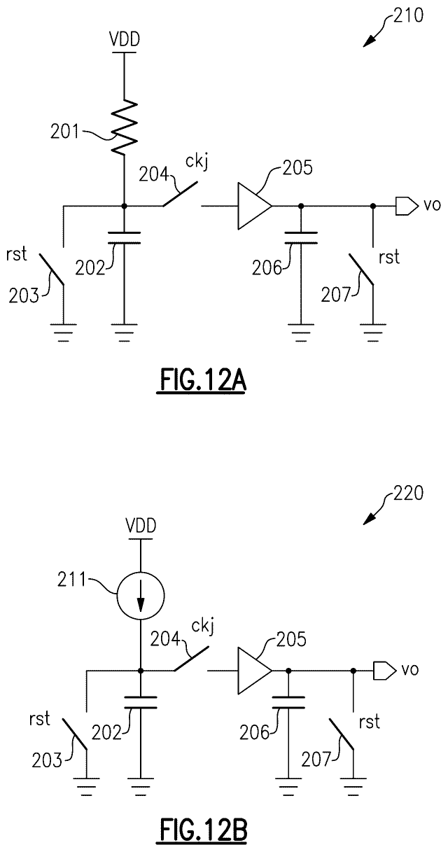

FIG. 12A is a schematic diagram of another embodiment of a jitter measuring circuit 210. The jitter measuring circuit 210 includes a resistor 201, a capacitor 202, a first reset switch 203 (controlled by a reset control signal rst), a test clock switch 204 (controlled by a test clock signal corresponding to the clock signal under jitter testing), a buffer 205, an output capacitor 206, and a second reset switch 207 (controlled by the reset control signal rst).

In the illustrated embodiment, the resistor 201 is electrically connected between a supply voltage VDD and a sampling node. Additionally, the first reset switch 203 and the capacitor 202 are electrically connected in parallel between the sampling node and a ground voltage. Additionally, the test clock switch 204 is electrically connected between the sampling node and an input to the buffer 205. Furthermore, the output capacitor 206 and the second reset switch 207 are electrically connected in parallel between an output of the buffer 205 and the ground voltage.

The jitter measuring circuit 210 operates to generate an analog measurement voltage vo (corresponding to a voltage across the output capacitor 206) indicating a measured jitter of the test clock signal ckj. For example, after the voltage of the capacitor 202 is reset to the ground voltage using the first reset switch 203, the test clock signal serves to sample the voltage across the capacitor 202 as the capacitor 202 is being charged by the current through the resistor 201. The samples collected by such sampling can be observed over time (for instance, by statistical calculations, such as standard deviation) to estimate jitter of the test clock signal ckj.

Accordingly, the jitter measuring circuit 210 can obtain jitter measurement of the test clock signal ckj and operate without needing a reference clock signal. However, the jitter measuring circuit 210 can have higher current draw, limited range, and/or larger component count and circuit area relative to the jitter measuring circuit 50 of FIG. 4A.

FIG. 12B is a schematic diagram of another embodiment of a jitter measuring circuit 220. The jitter measuring circuit 220 includes a current source 211, a capacitor 202, a first reset switch 203 (controlled by a reset control signal rst), a test clock switch 204 (controlled by a test clock signal corresponding to the clock signal under jitter testing), a buffer 205, an output capacitor 206, and a second reset switch 207 (controlled by the reset control signal rst).

The jitter measuring circuit 220 of FIG. 12B is similar to the jitter measuring circuit 210 of FIG. 12A, except that the jitter measuring circuit 220 of FIG. 12B includes the current source 211 rather than the resistor 201. Using the current source 211 can provide a constant slew rate for charging the capacitor 202 at the expense of increased circuit complexity and/or size.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A jitter measurement system comprising:
a jitter measuring circuit configured to obtain a plurality of analog jitter measurements of a test clock signal of a phase-locked loop;
an analog-to-digital converter configured to convert the plurality of analog jitter measurements to a plurality of digital jitter measurements; and
a digital signal processing circuit configured to process the plurality of digital jitter measurements to estimate a jitter of the test clock signal.

2. The jitter measurement system of claim 1 wherein the jitter measuring circuit includes a capacitor electrically connected between an output node and a first reference voltage, a reference clock voltage-controlled current source controlled by a reference clock signal, and a test clock switch controlled by the test clock signal, the test clock switch and the voltage-controlled current source electrically connected in series between the output node and the first reference voltage.

3. The jitter measurement system of claim 2 wherein an output voltage at the output node generates a jitter measurement voltage proportional to a phase difference between the test clock signal and the reference clock signal.

4. The jitter measurement system of claim 2 wherein the jitter measuring circuit further includes a ramp control circuit configured to control a slew of the reference clock signal based on a slew control signal.

5. The jitter measurement system of claim 2 wherein the jitter measuring circuit further includes a reset switch electrically connected between a second reference voltage and the output node.

6. The jitter measurement system of claim 5 wherein the reference clock voltage-controlled current source includes a first n-type metal-oxide-semiconductor transistor, the test clock switch includes a second n-type metal-oxide-semiconductor transistor, and the reset switch includes a p-type metal-oxide-semiconductor transistor.

7. The jitter measurement system of claim 1 wherein the digital signal processing circuit is further configured to estimate the jitter of the test clock signal based on a standard deviation or a variance of a first derivative of the plurality of digital jitter measurements.

8. The jitter measurement system of claim 1 wherein the digital signal processing circuit is configured to compare the estimate of the jitter of the test clock signal to a reference jitter threshold.

9. The jitter measurement system of claim 8 wherein the digital signal processing circuit is further configured to generate the reference jitter threshold from a plurality of digital reference jitter measurements obtained from an input clock signal of a known jitter.

10. The jitter measurement system of claim 1 wherein the jitter measuring circuit and the phase-locked loop are implemented on a common semiconductor chip, and the phase-locked loop includes a time-stamper including the analog-to-digital converter.

11. The jitter measurement system of claim 10 wherein the time-stamper is operable in a first mode in which the analog-to-digital converter outputs digital data for generating digital time stamps, and a second mode in which the analog-to-digital converter outputs the plurality of digital jitter measurements for jitter testing.

12. The jitter measurement system of claim 1 wherein the analog-to-digital converter includes a differential voltage input and the jitter measuring circuit includes a single-ended voltage output, the jitter measurement system further including a single-ended to differential voltage buffer coupled between the single-ended voltage output and the differential voltage input.

13. The jitter measurement system of claim 1 wherein the jitter measuring circuit includes a capacitor electrically connected between a sampling node and a first reference voltage, a buffer, and a sampling switch controlled by the test clock signal and electrically connected between the sampling node and an input to the buffer.

14. The jitter measurement system of claim 13 wherein the jitter measuring circuit further includes a resistor electrically connected between the sampling node and a second reference voltage.

15. The jitter measurement system of claim 13 wherein the jitter measuring circuit further includes a current source electrically connected between the sampling node and a second reference voltage.

16. A method of jitter measurement, the method comprising:
obtaining a plurality of analog jitter measurements of a test clock signal of a phase-locked loop using a jitter measuring circuit;
converting the plurality of analog jitter measurements to a plurality of digital jitter measurements using an analog-to-digital converter; and
processing the plurality of digital jitter measurements to estimate a jitter of the test clock signal using a digital signal processing circuit.

17. The method of claim 16 wherein the jitter measuring circuit includes a capacitor electrically connected between an output node and a first reference voltage, a reference clock voltage-controlled current source controlled by a reference clock signal, and a test clock switch controlled by the test clock signal, the test clock switch and the reference clock voltage-controlled current source electrically connected in series between the output node and the first reference voltage.

18. The method of claim 16 further comprising using the digital signal processing circuit to estimate the jitter of the test clock signal based on a standard deviation or a variance of a first derivative of the plurality of digital jitter measurements.

19. The method of claim 16 further comprising using the digital signal processing circuit to compare the estimate of the jitter of the test clock signal to a reference jitter threshold, and using the digital signal processing circuit to generate the reference jitter threshold from a plurality of digital reference jitter measurements obtained from an input clock signal of a known jitter.

20. A semiconductor chip comprising:
a phase-locked loop configured to generate a test clock signal, the phase-locked loop including a time-stamper that includes an analog-to-digital converter; and
a jitter measuring circuit configured to obtain a plurality of analog jitter measurements of the test clock signal of the phase-locked loop, the analog-to-digital converter configured to convert the plurality of analog jitter measurements to a plurality of digital jitter measurements for estimating a jitter of the test clock signal.
